(19) United States
(12) Patent Application Publication
(10) Pub. No.: US 2016/0049616 A1
(43) Pub. Date: Feb. 18, 2016

(54) LIGHT EMITTING DEVICE

(71) Applicants: PIONEER CORPORATION, Kawasaki-shi (JP); TOHOKU PIONEER CORPORATION, Tendo-shi (JP)

(72) Inventor: Shinji NAKAJIMA, Yonezawa-shi (JP)

(21) Appl. No.: 14/780,498

(22) PCT Filed: Apr. 1, 2013
(86) PCT No.: PCT/JP2013/059825

§ 371 Date: Sep. 25, 2015

(51) Int. Cl. H01L 51/52; H01L 27/32

(52) U.S. Cl. CPC H01L 51/5284; H01L 27/3244; H01L 51/5271; H01L 51/5206; H01L 51/5253; H01L 51/5234

(57) ABSTRACT

A second electrode (150) is formed of a semi-transparent film. A light-transmitting film (210) and a reflective film (220) are formed on the second electrode (150). A laminated structure of the second electrode (150), the light-transmitting film (210), and the reflective film (220) is also formed between organic EL elements (lamination portion of a first electrode (110), an organic layer (140), and the second electrode (150)) adjacent to each other. A portion of external light entering a substrate (100) is reflected by the second electrode (150), and the remainder passes through the second electrode (150). Light passing through the second electrode (150) is reflected by the reflective film (220) through the light-transmitting film (210). A portion of this reflected light is emitted to the outside through the second electrode (150), but the remainder is reflected by the second electrode (150) and is directed to the reflective film (220) again.

### TECHNICAL FIELD

The present invention relates to a light emitting device.

### BACKGROUND ART

There is organic electroluminescence (EL) as one of light sources for an illumination device or a display. In organic EL, external light incident on an organic EL element may be internally reflected, and may be mixed with light emitted from the organic EL. On the other hand, Patent Document 1 discloses that a light portion absorbing film and a transparent film are laminated between an electrode and an EL electrooptic element, although this is not an organic EL element. In a technique disclosed in Patent Document 1, it is required for the electrode to reflect light toward the light portion absorbing film and the transparent film in order to suppress the reflection of external light.

### RELATED DOCUMENT

### Patent Document

[Patent Document 1] Japanese Unexamined Patent Application Publication No. H2(1990)-276191

### SUMMARY OF THE INVENTION

However, in the technique disclosed in Patent Document 1, it is not possible to suppress the reflection of external light in a region of a light emitting device in which the electrode is not provided, that is, a region which does not serve as a light-emitting portion.

The invention that solves this problem includes an example in which, in a light emitting device having a light-emitting portion, external light is prevented from being reflected in a region which does not serve as the light-emitting portion.

According to the invention of claim 1, there is provided a substrate; a light-emitting portion, provided in the substrate, which includes an organic EL element; and a non-light-emitting portion, provided in the substrate, which does not include the organic EL element, in which a semi-light-transmitting film and a reflective film that cover the non-light-emitting portion are provided.

### BRIEF DESCRIPTION OF THE DRAWINGS

The above-mentioned objects, other objects, features and advantages will be made clearer from the preferred embodiment described below, and the following accompanying drawings.

FIG. 1 is a plan view illustrating a configuration of a light emitting device according to an embodiment.

FIG. 2 is a cross-sectional view taken along line A-A of FIG. 1.

FIG. 3 is a cross-sectional view taken along line C-C of FIG. 1.

FIG. 4 is a cross-sectional view taken along line B-B of FIG. 1.

FIG. 5 is a diagram illustrating positions of a light-emitting portion and a non-light-emitting portion which are included in the light emitting device.

FIG. 6 is a plan view illustrating a configuration of a light emitting device according to Example 1.

FIG. 7 is a cross-sectional view taken along line A-A of FIG. 6.

FIG. 8 is a cross-sectional view taken along line C-C of FIG. 6.

FIG. 9 is a cross-sectional view illustrating a configuration of a light emitting device according to Example 2.

FIG. 10 is a cross-sectional view illustrating a configuration of the light emitting device according to Example 2.

FIG. 11 is a cross-sectional view illustrating a configuration of a light emitting device according to Example 3.

FIG. 12 is a diagram illustrating reflection of light within a light emitting device.

FIG. 13 is a diagram illustrating wavelength dependence of a refractive index.

### DESCRIPTION OF EMBODIMENTS

Hereinafter, an embodiment of the present invention will be described with reference to the accompanying drawings. In all the drawings, like elements are referenced by like reference numerals and the descriptions thereof will not be repeated.

### Embodiment

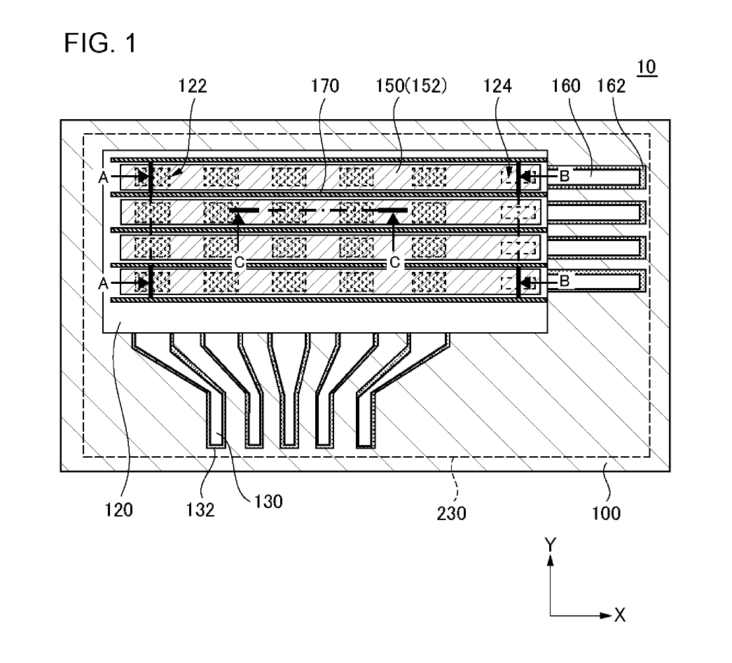

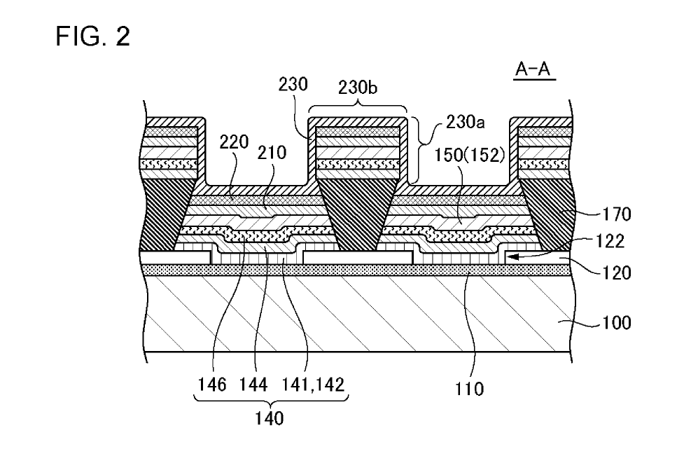

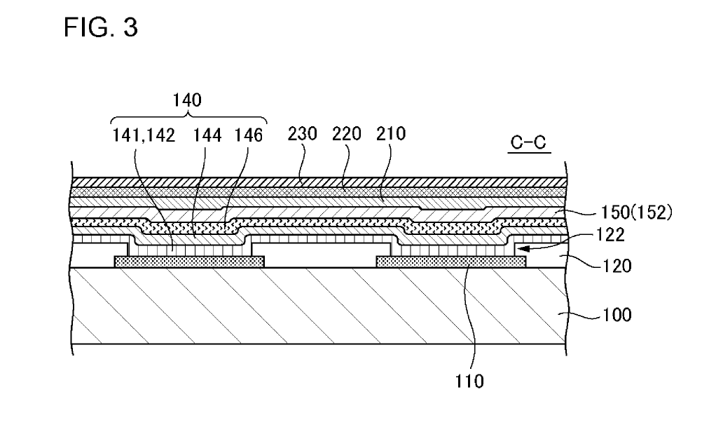

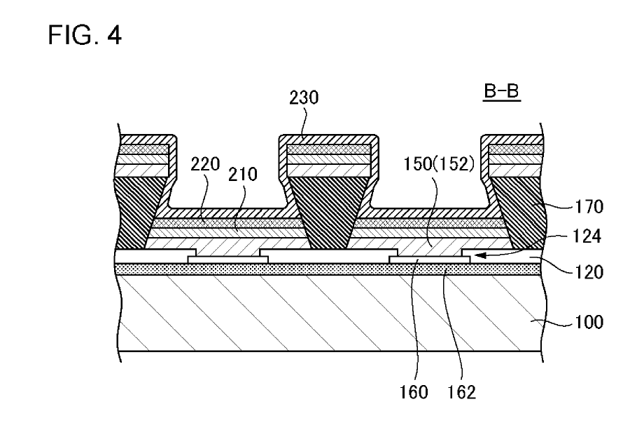

FIG. 1 is a plan view illustrating a configuration of a light emitting device 10 according to an embodiment. FIG. 2 is a cross-sectional view taken along line A-A of FIG. 1, FIG. 3 is a cross-sectional view taken along line C-C of FIG. 1, and FIG. 4 is a cross-sectional view taken along line B-B of FIG. 1.

The light emitting device 10 is, for example, a display or an illumination device. When the light emitting device 10 is an illumination device, the light emitting device 10 may be a device that realizes color rendering properties by including a first electrode 110, an organic layer 140, and a second electrode 150. The light emitting device 10 as an illumination device may be configured such that the first electrode 110, the organic layer 140, and the second electrode 150 are formed to be flush with each other without forming a partition wall 170 as a structure described later. Meanwhile, in the following description, a case where the light emitting device 10 is a display is illustrated.

The light emitting device 10 includes a substrate 100, the first electrode 110 (lower electrode), an organic EL element, an insulating layer 120, a plurality of first openings 122, a plurality of second openings 124, a plurality of extraction interconnects 130, the organic layer 140, the second electrode 150 (upper electrode), a plurality of extraction interconnects 160, and a plurality of partition walls 170. The insulating layer 120 and the partition wall 170 are examples of a structure which is formed on the substrate. The organic EL element is constituted by a laminate with the organic layer 140 interposed between the first electrode 110 and the second electrode 150. This organic EL element is located between the plurality of partition walls 170. That is, the organic EL element and the extraction interconnect 160 are located on one surface side of the substrate 100. A light-emitting portion is constituted by the organic EL element.

The substrate 100 is formed of, for example, glass or a resin material, but may be formed of other materials.

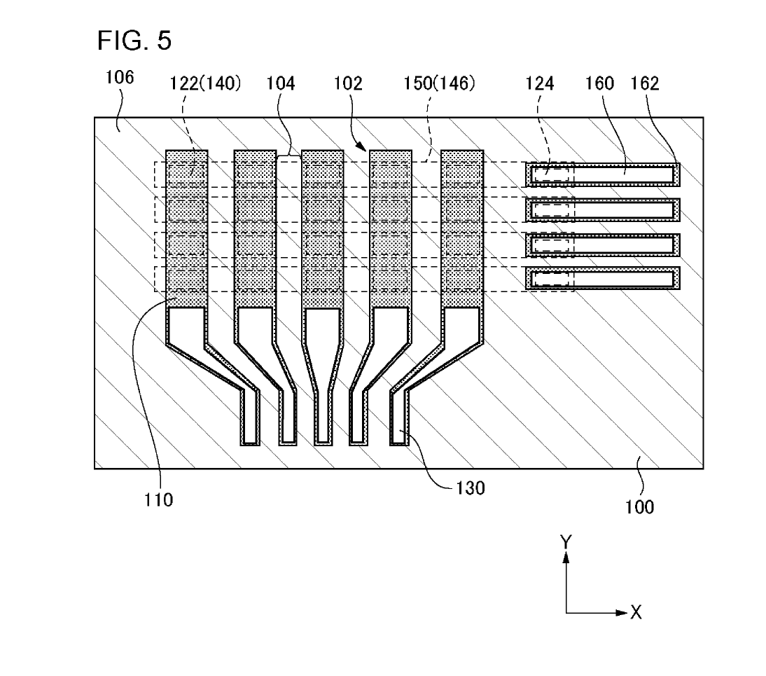

The first electrode 110 is formed on the first surface side of the substrate 100, and extends linearly in a first direction (Y direction in FIG. 1) as shown in FIG. 5 described later. The first electrode 110 is, for example, a transparent electrode formed of an inorganic material such as an indium thin oxide (ITO) or an indium zinc oxide (IZO), or a conductive polymer such as a polythiophene derivative. In addition, the first electrode 110 is formed as a conductor (first conductor). The first electrode 110 may be a metal thin film which is small in thickness to such an extent that light is transmitted. The end of the first electrode 110 is connected to the extraction interconnect 130. In the shown example, the first conductor is constituted by a layer having the first electrode 110 and the extraction interconnect 130 laminated therein.

The extraction interconnect 130 is an interconnect that connects the first electrode 110 to the outside including electronic parts such as a driving IC. The extraction interconnect 130 is, for example, a metal interconnect formed of a conductive oxide material such as ITO or IZO, a metal material such as Al, Cr or Ag, or an alloy thereof, but may be an interconnect formed of conductive materials other than a metal. In addition, the extraction interconnect 130 may include a laminated structure in which a plurality of layers are laminated. In this case, one layer of the extraction interconnect is constituted by the first conductor, and the first electrode and one layer of the extraction interconnect 130 may be continuously formed of the first conductor. In the example shown in FIG. 1, an extraction interconnect 132 and the extraction interconnect 130 are formed in this order on the substrate 100. The extraction interconnect 132 is formed of the same material as that of the first electrode 110. In the example shown in the drawing, the extraction interconnects 130 and 132 are formed in the vicinity of a first opening 122 closest to the extraction interconnect 130. In the shown example, the first electrode 110 is covered with an insulating layer, but at least a portion of the extraction interconnect 130 and the extraction interconnect 132 which are electrically connected to the first electrode 110 may be covered with an insulating layer.

As shown in FIGS. 1 to 4, the insulating layer 120 is formed on a plurality of first electrodes 110 and in regions located therebetween. The insulating layer 120 is formed of a photosensitive resin such as a polyimide-based resin, and is formed in a desired pattern by exposure and development. As the insulating layer 120, for example, a positive-type photosensitive resin is used. Meanwhile, the insulating layer 120 may be resins other than a polyimide-based resin, for example, an epoxy-based resin or an acrylic-based resin.

The plurality of first openings 122 and the plurality of second openings 124 are formed in the insulating layer 120. The first opening 122 is located at a point of intersection between the first electrode 110 and a second conductor 152 serving as the second electrode 150 when seen in a plan view. Meanwhile, a portion of the second conductor 152 which is located within the first opening 122 serves as the second electrode 150. The plurality of first openings 122 are provided at a predetermined distance. The plurality of first openings 122 are lined up in a direction in which the first electrode 110 extends. In addition, the plurality of first openings 122 are also lined up in a direction in which the second conductor 152 extends. For this reason, the plurality of first openings 122 are disposed so as to constitute a matrix.

The second opening 124 is located at one end of each of a plurality of second conductors 152 when seen in a plan view. In addition, the second opening 124 is disposed along one side of the matrix constituted by the first openings 122. When seen in a direction along the one side (for example, Y direction in FIG. 1), the second openings 124 are disposed at a predetermined interval in a direction along the first electrode 110. The extraction interconnect 160 or a portion of the extraction interconnect 160 is exposed from the second opening 124.

Meanwhile, the insulating layer 120 having the first opening 122 and the insulating layer 120 having the second opening 124 may be formed of the same material, and may be formed of different materials. In addition, the insulating layer 120 having the second opening 124 may be formed on the outer circumferential portion side of the substrate 100 with respect to the insulating layer 120 having the first opening 122. In addition, the insulating layer 120 having the first opening 122 and the insulating layer 120 having the second opening 124 may be a continuous layer, and may be separated layers (partitioned).

The organic layer 140 is formed in a region overlapping the first opening 122. In the example shown in FIG. 2, the organic layer 140 is a layer in which a hole transport layer 142, a light-emitting layer 144, and an electron transport layer 146 are laminated. Meanwhile, a portion of the organic layer indicates, for example, the hole transport layer 142, the light-emitting layer 144, the electron transport layer 146, a hole injection layer 141 described later, or an electron injection layer. The hole transport layer 142 comes into contact with the first electrode 110, and the electron transport layer 146 comes into contact with the second electrode 150. In this manner, the organic layer 140 is interposed between the first electrode 110 and the second electrode 150.

Meanwhile, the hole injection layer 141 may be formed between the first electrode 110 and the hole transport layer 142, and the electron injection layer may be formed between the second electrode 150 and the electron transport layer 146. In addition, not all of the layers mentioned above are required. For example, when the recombination of holes and electrons occurs within the electron transport layer 146, the electron transport layer 146 also has a function of the light-emitting layer 144, and thus the light-emitting layer 144 is not required. In addition, at least one of the second conductors 152 serving as the first electrode 110, the hole injection layer, the hole transport layer 142, the electron transport layer 146, the electron injection layer, and the second electrode second electrode 150 may be formed using a coating method such an ink jet method. In addition, an electron injection layer formed of an inorganic material such as LiF may be provided between the organic layer 140 and the second electrode.

Meanwhile, in the examples shown in FIGS. 2 and 3, a case is shown in which each of the respective layers constituting the organic layer 140 protrude to the outside of the first opening 122. As shown in FIG. 3, each of the respective layers constituting the organic layer 140 may or may not be continuously formed between the first openings 122 adjacent to each other in a direction in which the partition wall 170 extends. However, as shown in FIG. 4, the organic layer 140 is not formed in the second opening 124.

The organic layer 140 is interposed between the first electrode 110 and the second electrode 150. As shown in FIGS. 1 to 4, the second electrode 150 is formed above the organic layer 140, and extends in a second direction (X direction in FIG. 1) intersecting the first direction. The second electrode 150 is electrically connected to the organic layer 140. For example, the second electrode 150 may be formed on the organic layer 140, and may be formed on a conductive layer formed on the organic layer 140. The second conductor 152 serving as the second electrode 150 is, for example, a metal layer formed of a metal material such as Ag or Al, or a layer formed of a conductive oxide material such as IZO. The light emitting device 10 includes a plurality of second conductors 152 parallel to each other. One second conductor 152 is formed in a direction passing over the plurality of first openings 122. In addition, the second conductor 152 is connected to the extraction interconnect 160. In the shown example, the end of the second conductor 152 is located on the second opening 124, and thus the second conductor 152 and the extraction interconnect 160 are connected to each other in the second opening 124.

In the example of FIG. 1, an extraction interconnect 162 is formed below the extraction interconnect 160. In the example shown in FIG. 1, the width of the extraction interconnect 162 is larger than the width of the extraction interconnect 160, but may be smaller than that. The extraction interconnects 160 and 162 is formed in a region of the substrate 100 on the first surface side in which the first electrode 110 and the extraction interconnects 130 and 132 are not formed. The extraction interconnect 160 may be formed, for example, simultaneously with the extraction interconnect 130, and may be formed by a process separate from that in which the extraction interconnect 130 is formed. Similarly, the extraction interconnect 162 may be formed, for example, simultaneously with the extraction interconnect 132, and may be formed by a process separate from that in which the extraction interconnect 132 is formed.

The extraction interconnect 162 is formed of the same or different material as or from a material constituting the first electrode 110. Here, an example of the same material includes an ITO having the same or different composition as or from that of an ITO constituting the first electrode 110, or a conductive oxide material such as IZO, when the first electrode 110 is formed of an ITO which is a conductive oxide material. In addition, an example of a different material includes a metal material such as Al, or the like.

A portion of one end side (light-emitting portion side) of the extraction interconnect 160 is covered with the insulating layer 120, and is exposed by the second opening 124. In the second opening 124, the second conductor 152 is connected to the extraction interconnect 160. In addition, a portion of the other end side (outer circumferential portion side of the substrate) of the extraction interconnect 160 is extracted to the outside of the insulating layer 120. That is, the other end side of the extraction interconnect 160 is exposed from the insulating layer 120. In a portion of the other end side of the extraction interconnect 160, the extraction interconnect 160 extends in a direction approximately orthogonal to the extraction interconnect 130.

The partition wall 170 is formed between the second conductors 152 adjacent to each other. The partition wall 170 extends parallel to the second conductor 152, that is, in the second direction. The foundation of the partition wall 170 is, for example, the insulating layer 120. The partition wall 170 is, for example, a photosensitive resin such as a polyimide-based resin, and is formed in a desired pattern by exposure and development. The partition wall 170 is formed using, for example, a negative photosensitive resin. Meanwhile, the partition wall 170 may be formed of resins other than a polyimide-based resin, for example, an epoxy-based resin or an acrylic-based resin, or an inorganic material such as silicon dioxide.

The partition wall 170 is formed in a shape (inverted trapezoid) which is trapezoidal in cross-section and is turned upside down. That is, the width of the upper surface of the partition wall 170 is larger than the width of the lower surface of the partition wall 170. For this reason, the partition wall 170 is formed prior to the second conductor 152 (second electrode 150), and the second conductors 152 are formed to be flush with each other on one surface side of the substrate using a vapor deposition method or a sputtering method, thereby allowing the plurality of second electrodes 150 to be collectively formed. Since the second conductors 152 formed to be flush with each other are partitioned by the partition wall 170, the plurality of second conductors 152 are provided on the organic layer 140. A position where the second conductors 152 are partitioned includes, for example, an upper portion of the insulating layer 120 which is the foundation of the partition wall 170, the lateral side of the partition wall 170, or the like. The second conductor 152 can be patterned in any shape such as a stripe shape, a dot shape, an icon shape, or a curve by changing the extending direction of the partition wall 170. Meanwhile, the second conductor 152 is formed on the partition wall 170.

In addition, when the organic layer 140 is formed of a coating material, the organic layer 140 is formed by applying the coating material to the plurality of first openings 122. When the coating material is applied to the plurality of first openings, the partition wall 170 may have a function of preventing the organic layer from being continuously formed from the first opening 122 located on one side of the partition wall 170 to the first opening 122 located on the other side thereof, caused by connection of the coating material applied to the first openings 122 located on both sides of the partition wall 170. In this case, the partition wall 170 is formed prior to the organic layer 140.

In the present embodiment, the second electrode 150 (second conductor 152) is changed to a semi-transparent film by being formed of a material having optical transparency, adjusting a film thickness, or the like. For example, when the second electrode 150 is formed of Al or Ag, the film thickness of the second electrode 150 is set to be equal to or greater than 10 nm and equal to less than 50 nm, and thus the second electrode 150 can be changed to a semi-transparent film. However, the film thickness of the second electrode 150 is not limited thereto.

A light-transmitting film 210 and a reflective film 220 are formed on the second conductor 152. The light-transmitting film 210 is, for example, a film formed of an organic material such as tris(8-hydroxyquinolinato)aluminum (Alq3), or an inorganic material having optical transparency which is obtained by mixing Cr and SiO₂, and the film thickness thereof is appropriately changed as necessary. The light transmittance of the light-transmitting film 210 is lower than the light transmittance of the first electrode 110.

When the light-transmitting film 210 is formed of an organic material, the light-transmitting film 210 may be formed using a coating method (for example, spray application, dispenser application, ink jet, or printing method), and may be formed using a vapor deposition method. When the light-transmitting film 210 is formed using a coating method, the film is not formed on the upper surface of the partition wall 170. On the other hand, when the light-transmitting film 210 is formed using a vapor deposition method, the film is also formed on the upper surface of the partition wall 170. In addition, the light-transmitting film 210 may also be formed on the lateral side of the partition wall 170, and on the lateral side of a laminated film located on the partition wall 170.

The reflective film 220 is, for example, a film of a metal such as Al or Ag, and the film thickness thereof is, for example, equal to or greater than 80 nm. The reflective film 220 is formed using, for example, a vapor deposition method. In this case, the reflective film 220 is also formed on the partition wall 170.

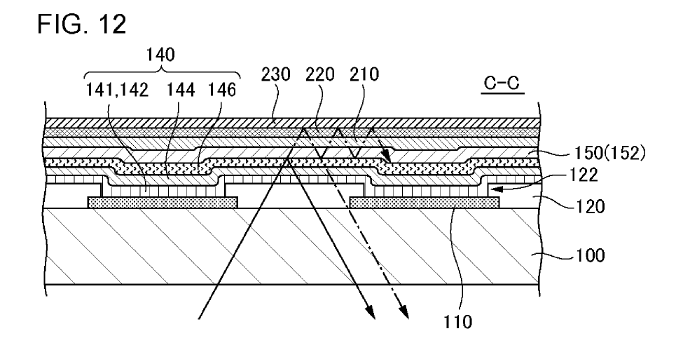

As shown by arrows in a C-C cross-sectional view of FIG. 12, external light enters the inside of the light emitting device 10 from the second surface side of the substrate 100. A portion of the external light (for example, energy equal to or greater than 40% and equal to or less than 60% of the total energy when the external light is incident on the substrate 100) is reflected by the second conductor 152, and the remainder passes through the second conductor 152. Light passing through the second conductor 152 is reflected by the reflective film 220 through the light-transmitting film 210. A portion of the external light reflected by the reflective film 220 is emitted to the first surface side (outside) of the substrate 100 through the second conductor 152, but the remainder is reflected by the second electrode 150, and is directed to the reflective film 220 again.

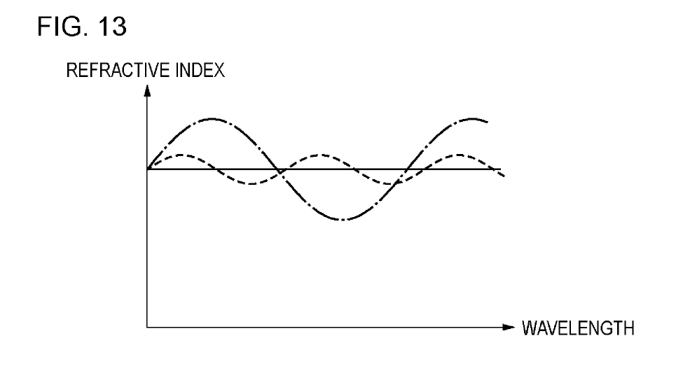

In this manner, a portion of the external light is trapped between the second conductor 152 and the reflective film 220. Therefore, the reflection of the external light can be suppressed in the light emitting device 10. It is possible to reduce the wavelength dependence of the suppression of the external light reflection by providing the light-transmitting film 210. When the wavelength dependence of the refractive index of the light-transmitting film 210 is low, the wavelength dependence of the suppression of the external light reflection becomes particularly lower. Here, the wording “wavelength dependence of the refractive index is low” includes a case where the refractive index is flat (or substantially flat), for example, from a small wavelength to a large wavelength, as shown in a solid line and a dotted line of FIG. 13, and refers to a case where large peaks and dips are not seen in the refractive index unlike an example shown by a dashed-dotted line. In addition, a component of light, reflected by the reflective film 220 and then passing through the second conductor 152, in which the thickness of the light-transmitting film 210 is set to 2n×λ/4 (where, λ is a wavelength, and n is an integer) interferes with light incident on the second conductor 152 from the substrate 100 side, which results in mutual cancellation. Therefore, it is possible to further suppress the reflection of the external light in the light emitting device 10.

In the present embodiment, as described later with reference to FIG. 5, the light-transmitting film 210 and the reflective film 220 are also formed on a portion (portion which is not the second electrode 150) of the second conductor 152 which is not an organic EL element. For this reason, the suppression of the external light reflection also occurs in a region of the light emitting device 10 in which the organic EL element is not formed.

In addition, a sealing film 230 is formed on the reflective film 220. The sealing film 230 is formed using, for example, an atomic layer deposition (ALD) method. A film formed by the ALD method has high step coverage. Here, step coverage refers to the uniformity of film thickness in a portion having a step. The wording “high step coverage” means that the uniformity of film thickness is also high in a portion having a step, and the wording “low step coverage” means that the uniformity of film thickness is low in a portion having a step. For example, in the example shown in FIG. 2, a step is formed in the foundation of the sealing film 230 depending on the presence or absence of the partition wall 170. The sealing film 230 has a small difference between the film thickness of a portion (230a) located on the lateral side of the step and the film thickness of a portion (230b) located on the upper surface of the step. The sealing film 230 is, for example, an oxide film such as an aluminum oxide, and the film thickness thereof is, for example, equal to or greater than 10 nm and equal to or less than 30 nm. As shown in FIG. 1, the sealing film 230 covers the insulating layer 120, the extraction interconnect 160, and the extraction interconnect 130. However, the sealing film 230 may not cover the ends of the extraction interconnects 130 and 160 which are not covered with the insulating layer 120. Meanwhile, the sealing film 230 may be formed using film formation methods other than the ALD method, for example, a CVD method.

Meanwhile, the sealing film 230 has relatively large internal stress. After the sealing film 230 having such internal stress is formed, a shape change (for example, contraction) may occur in the sealing film 230 due to the internal stress. Particularly, when the sealing film 230 is formed directly on the second conductor 152, and when the second conductor 152 is adhered to the sealing film 230, stress due to the sealing film 230 is applied to the second electrode 150, and thus even the shape of the second conductor 152 is changed. For this reason, peeling of a film or the like occurs at an interface between the second electrode 150 and the organic layer 140 or within the organic layer 140. In the present embodiment, since the light-transmitting film 210 is provided between the second electrode 150 and the sealing film 230, such peeling or the like can be prevented from occurring. Particularly, when the light-transmitting film 210 and the sealing film 230 are adhered to each other, the stress of the sealing film 230 can be absorbed, or the shape of the sealing film 230 is prevented from changing (the light-transmitting film adds a resisting force to the deformation of the sealing film 230), and thus it is possible to suppress the peeling of a film or the like described above. Particularly, when the adhesion between the light-transmitting film 210 and the second conductor 152 is low, it is possible to prevent the stress of the sealing film 230 from being applied to the second conductor 152. On the other hand, when the adhesion between the light-transmitting film 210 and the sealing film 230 is low, the stress of the sealing film 230 is not applied to the light-transmitting film 210, and thus it is possible to prevent the stress of the sealing film 230 from being applied to the second conductor 152. In this case, the adhesion between the light-transmitting film 210 and the second conductor 152 may be high or low.

In addition, when the light-transmitting film 210 is formed of an organic film, the adhesion between the light-transmitting film 210 and the sealing film 230 deteriorates. For this reason, a fracture occurs due to the shape of the sealing film 230 being greatly deformed, and thus sealing properties may lower. On the other hand, in the present embodiment, the reflective film 220 is provided between the light-transmitting film 210 and the sealing film 230. When the reflective film 220 adheres to the sealing film 230, it is possible to prevent the shape of the sealing film 230 from being deformed, and to prevent sealing properties from lowering due to a fracture or the like occurring in the sealing film 230.

FIG. 5 is a diagram illustrating positions of a light-emitting portion and a non-light-emitting portion which are included in the light emitting device 10. A light-emitting portion 102 is a region (region serving as an organic EL element) of the organic layer 140 which emits light. Specifically, a portion of the organic layer 140 which is interposed between the first electrode 110 and the second electrode 150 serves as the light-emitting portion 102.

The second electrode 150, the light-transmitting film 210, and the reflective film 220 are formed in the light-emitting portion 102. Therefore, it is possible to suppress the reflection of external light in the light-emitting portion 102.

External light is also incident on a region (non-light-emitting portion 104) located between the light-emitting portions 102 adjacent to each other. On the other hand, in the present embodiment, the second conductor 152, the light-transmitting film 210, and the reflective film 220 which are made of the same material as that of the second electrode 150 are formed. Therefore, it is also possible to suppress the reflection of external light in the non-light-emitting portion 104.

In addition, in a region that surrounds a region having a plurality of light-emitting portions 102 formed therein, that is, a region (non-light-emitting portion 106) located at the edge of the substrate 100, when the second conductor 152, the light-transmitting film 210, and the reflective film 220, some of which serve as the second electrode 150, are formed, it is also possible to suppress the reflection of external light. In this case, it is preferable that the second conductor 152 in the non-light-emitting portion 106 is separated from the second electrode 150 in the light-emitting portion 102 and the non-light-emitting portion 104.

Next, a method of manufacturing the light emitting device 10 will be described. First, a conductive layer serving as the first electrode 110 is formed on the substrate 100, and this conductive layer is selectively removed using etching (for example, dry etching or wet etching) or the like. Thereby, the first electrode 110 and the extraction interconnects 132 and 162 are formed on the substrate 100.

Next, a conductive layer serving as the extraction interconnects 130 and 160 is formed on the substrate 100, the first electrode 110, and the extraction interconnect 162, and this conductive layer is selectively removed using etching (for example, dry etching or wet etching) or the like. Thereby, the extraction interconnects 130 and 160 are formed.

Next, an insulating layer is formed on the substrate 100, the first electrode 110, and the extraction interconnects 130 and 160, and this insulating layer is selectively removed using etching (for example, dry etching or wet etching) or the like. Thereby, the insulating layer 120, the first opening 122, and the second opening 124 are formed. For example, when the insulating layer 120 is formed of polyimide, heat treatment is performed on the insulating layer 120. Thereby, the imidization of the insulating layer 120 proceeds.

Next, an insulating film serving as the partition wall 170 is formed on the insulating layer 120, and this insulating film is selectively removed using etching (for example, dry etching or wet etching) or the like. Thereby, the partition wall 170 is formed. When the partition wall 170 is formed of a photosensitive insulating film, the cross-section of the partition wall 170 is formed in an inverted trapezoidal shape by adjusting conditions during exposure and development.

When the partition wall 170 is a negative resist, a portion of this negative resist which is irradiated with irradiation light from an exposure light source is cured. The partition wall 170 is formed by dissolving and removing an uncured portion of this negative resist using a developing solution.

Next, the hole injection layer 141, the hole transport layer 142, the light-emitting layer 144, the electron transport layer 146, and the electron injection layer are formed in this order within the first opening 122. At least the hole injection layer among these layers is formed using, for example, a coating method such as spray application, dispenser application, ink jet, or printing. In this case, a coating material enters the first opening 122, and the respective layers are formed by this coating material being dried. As the coating material used in the coating method, a high-molecular-weight material, a material containing a low-molecular-weight material in the high-molecular-weight material, or the like is suitable. Examples of the coating materials to be used may include a polyalkylthiophene derivative, a polyaniline derivative, triphenylamine, a sol-gel film of an inorganic compound, an organic compound film containing a Lewis acid, a conductive polymer, and the like. Meanwhile, the remaining layers (for example, electron transport layer 146) of the organic layer 140 are formed by a vapor deposition method. However, these layers may be formed using any of the aforementioned coating methods.

Next, the second electrode 150 is formed on the organic layer 140, for example, using a vapor deposition method or a sputtering method.

Meanwhile, layers other than the organic layer 140, for example, at least one of the first electrode 110, the insulating layer 120, the extraction interconnect 130, the extraction interconnect 160, the second electrode 150, and the partition wall 170 may also be formed using any of the aforementioned coating methods.

Next, the light-transmitting film 210, the reflective film 220, and the sealing film 230 are formed using the aforementioned method.

As described above, according to the present embodiment, the second electrode 150 is formed of a semi-transparent film. The light-transmitting film 210 and the reflective film 220 are formed on the second electrode 150. Therefore, it is possible to suppress the reflection of external light incident on the light emitting device 10. The laminated structure of the second electrode 150, the light-transmitting film 210, and the reflective film 220 are formed not only in the light-emitting portion 102, but also in the non-light-emitting portion 104. Therefore, it is also possible to suppress the reflection of external light in the non-light-emitting portion 104.

In addition, in the present embodiment, the second electrode 150 is formed of a semi-transparent film. For this reason, a semi-transparent film is not required to be formed separately from the second electrode 150. Therefore, it is possible to reduce the manufacturing cost of the light emitting device 10. Meanwhile, when the second electrode 150 has a light-transmissive property, a semi-transparent film may be provided on the second electrode 150.

### EXAMPLE 1

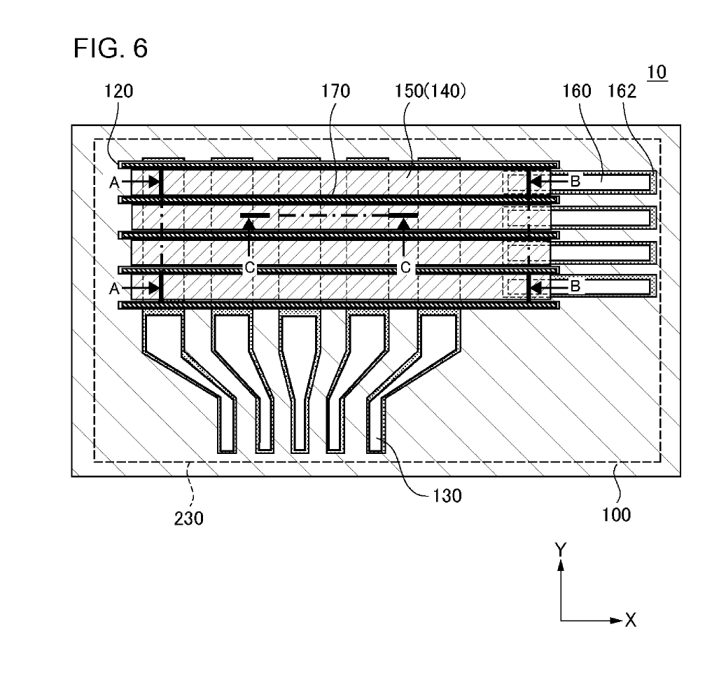

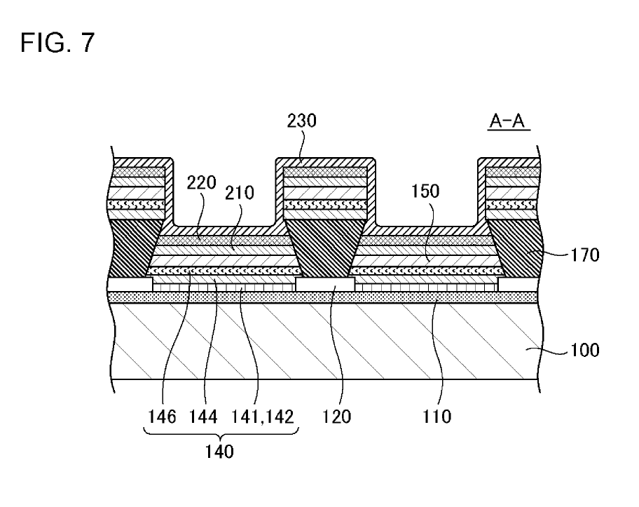

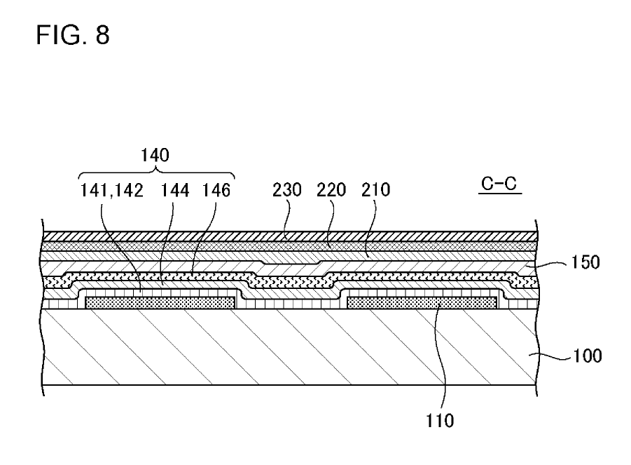

FIG. 6 is a plan view illustrating a configuration of the light emitting device 10 according to Example 1. FIG. 7 is a cross-sectional view taken along line A-A of FIG. 6, and FIG. 8 is a cross-sectional view taken along line C-C of FIG. 6. The light emitting device 10 according to the present example has the same configuration as that of the light emitting device 10 according to the embodiment, except for the following points.

First, the insulating layer 120 is provided only below the partition wall 170, and covers the upper surface of the first electrode 110, but does not cover the lateral side. That is, the lateral side of the first electrode 110 is exposed. For this reason, there is a non-formation region of the insulating film layer 120 in which the insulating layer 120 is not provided between two first electrodes 110 adjacent to each other. That is, the non-light-emitting portion 104 between the two first electrodes 110 adjacent to each other and between the insulating layers 120 located below two partition walls 170 adjacent to each other has optical transparency. That is, the transmittance of light of the non-light-emitting portion 104 in the non-formation region of the insulating layer 120 is higher than the transmittance of light of the insulating layer 120. In addition, the transmittance of light of the non-light-emitting portion 104 in the non-formation region of the insulating film 120 is higher than the transmittance of light in the non-light-emitting portion 104 having the insulating layer 120.

In addition, the substrate 100 is a thin plate (for example, resin film) made of a resin. For this reason, the light emitting device 10 has flexibility.

In the present example, it is also possible to suppress the reflection of external light in both the light-emitting portion 102 and the non-light-emitting portion 104. Particularly, in the present example, the amount of transmission of external light becomes larger in the non-light-emitting portion 104 in the non-formation region of the insulating layer 120. In such a case, it is also possible to suppress the reflection of external light.

In addition, when the insulating layer 120 is formed of polyimide, remaining moisture or gas in the insulating layer 120 gives rise to the possibility of the organic layer 140 being deteriorated due to the moisture or gas. In order to suppress this possibility, generally, it is necessary to raise the heat treatment temperature of the insulating layer 120. However, when the processing temperature of the insulating layer 120 is raised, it is not possible to use a resin as a material of the substrate 100.

On the other hand, in the present example, the insulating layer 120 is formed only below the partition wall 170. For this reason, a region in which an insulating layer having remaining moisture is formed therein can be made relatively small. In addition, the moisture or the like remaining in an insulating layer may be emitted from the partition wall 170, thus preventing the organic layer from being deteriorated. By lowering the heating temperature during the imidization of the insulating layer 120, it is possible to reduce the amount of moisture or gas emanating from the insulating layer 120 while the light emitting device 10 is used. Therefore, even when the substrate 100 is made of a resin, it is possible to suppress damage to the substrate 100 during the heat treatment of the insulating layer 120. It is possible to use the substrate 100 made of a resin by dropping the heating temperature of the insulating layer. In addition, it is possible to obtain a desired light emitting device 10 by reducing a region having the insulating layer 120 formed therein, and forming the insulating layer 120 only below the partition wall.

Meanwhile, when adhesion between a material used in the partition wall 170 and the substrate 100 is satisfactory, not providing the light emitting device 10 with the insulating layer 120 may be considered. When adhesion between a material used in the partition wall 170 and the substrate 100 is not satisfactory, the direct formation of the partition wall 170 on the substrate 100 makes it difficult to form the desired plural partition walls 170. Specifically, there is a case where the partition wall 170 to be provided is not present in some of regions on the substrate, a case where the partition wall 170 is not disposed upright but falls on the substrate 100, or the like. In the present example, the insulating layer 120 is provided below the partition wall 170, and desired plural partition walls 170 are formed.

### EXAMPLE 2

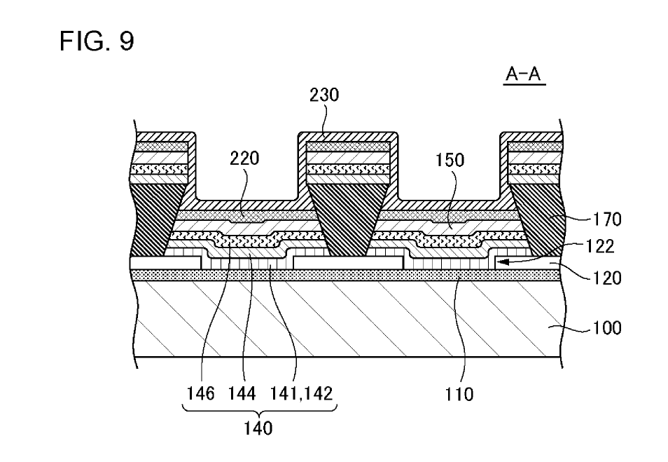

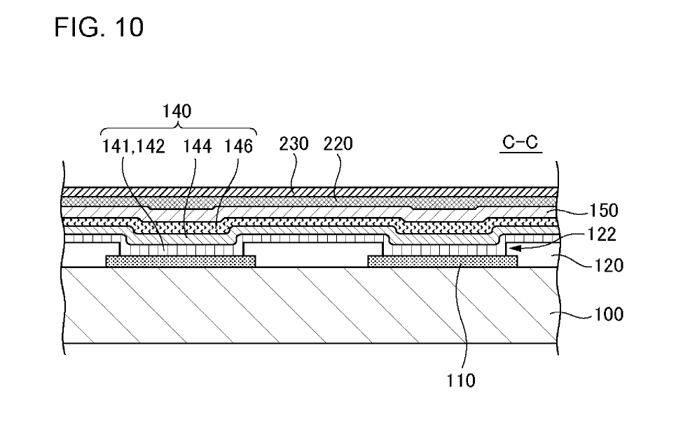

FIGS. 9 and 10 are cross-sectional views illustrating a configuration of a light emitting device 10 according to Example 2. FIG. 9 corresponds to FIG. 2 of the embodiment, and FIG. 10 corresponds to FIG. 3 of the embodiment. The light emitting device 10 according to Example 2 has the same configuration as that of the light emitting device 10 according to the embodiment or Example 1, except that the light-transmitting film 210 is not included therein.

In the present example, the laminated structure of the second electrode 150 and the reflective film 220 is formed not only in the light-emitting portion 102, but also in the non-light-emitting portion 104. Therefore, it is possible to suppress the reflection of external light in each of the light-emitting portion 102 and the non-light-emitting portion 104.

### EXAMPLE 3

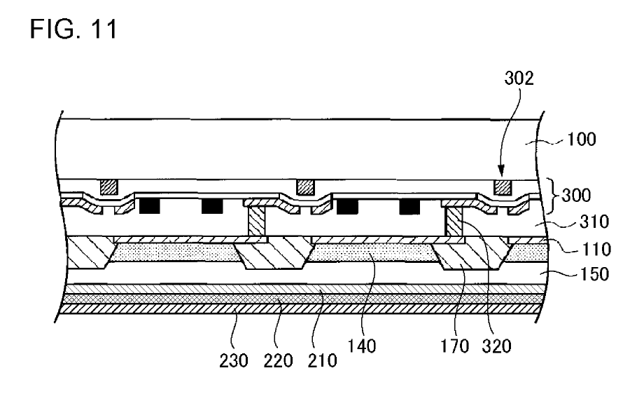

FIG. 11 is a cross-sectional view illustrating a configuration of a light emitting device 10 according to Example 3. The light emitting device 10 shown in the drawing is an active display.

Specifically, a transistor forming layer 300 and an insulating layer 310 are provided between the substrate 100 and the first electrode 110, a semiconductor layer (for example, silicon layer) is formed in the transistor forming layer 300, and a plurality of thin film transistors (TFT) 302 are formed using this semiconductor layer. The insulating layer 310 is formed between the transistor forming layer 300 and the first electrode 110. The insulating layer 310 also functions as a planarizing layer.

In the present example, the first electrode 110 is formed in pixel units. Each of the first electrodes 110 is connected to each of TFTs 302 different from each other through the conductors 320 embedded in the insulating layer 310. On the other hand, the second electrode 150 is a common electrode, and thus is also formed in a region between pixels and on the partition wall 170.

In the present example, the light-transmitting film 210, the reflective film 220, and the sealing film 230 are also formed on the second electrode 150. Meanwhile, the light-transmitting film 210 may not be formed.

In the present example, it is also possible to suppress the reflection of external light in each of the light-emitting portion 102 and the non-light-emitting portion 104.

As described above, although the embodiment and examples have been set forthwith reference to the accompanying drawings, they are merely illustrative of the present invention, and various configurations other than those stated above can be adopted.

1. A light emitting device comprising:
a substrate;
a light-emitting portion, provided in the substrate, which includes an organic EL element; and
a non-light-emitting portion, provided in the substrate, which does not include the organic EL element,
wherein a semi-light-transmitting film and a reflective film that cover the non-light-emitting portion are provided.

2. The light emitting device according to claim 1, wherein the semi-light-transmitting film and the reflective film are formed in the light-emitting portion.

3. The light emitting device according to claim 2, further comprising a light-transmitting film between the semi-light-transmitting film and the reflective film.

4. The light emitting device according to claim 3, wherein a portion of the semi-light-transmitting film is an upper electrode of the organic EL element.

5. The light emitting device according to claim 4, wherein light transmittance of the light-transmitting film is lower than light transmittance of a lower electrode of the organic EL element.

6. The light emitting device according to claim 5, wherein a plurality of the light-emitting portions are disposed over the substrate at a predetermined interval,
the non-light-emitting portion is disposed between the light-emitting portions adjacent to each other, and
the non-light-emitting portion has optical transparency.

7. The light emitting device according to claim 6, further comprising a structure which is formed in the non-light-emitting portion,
wherein, of the non-light-emitting portion, a non-formation region not formed with the structure has higher light transmittance than a formation region formed with the structure.

8. The light emitting device according to claim 7, further comprising a sealing film that covers the reflective film.

9. The light emitting device according to claim 8, wherein the sealing film is an oxide film.
